(19) United States
(12) Patent Application Publication
(10) Pub. No.: US 2015/0107660 A1
(43) Pub. Date: Apr. 23, 2015

(54) Super-Transparent Electrodes for Photovoltaic Applications

(71) Applicants: Krzysztof J. Kempa, Chestnut Hill, MA (US); Zhifeng Ren, Houston, TX (US); Yang Wang, Guangzhou (CN)

(72) Inventors: Krzysztof J. Kempa, Chestnut Hill, MA (US); Zhifeng Ren, Houston, TX (US); Yang Wang, Guangzhou (CN)

(73) Assignee: The Trustees of Boston College, Chestnut Hill, MA (US)

(21) Appl. No.: 14/129,428

(22) PCT Filed: Jun. 27, 2012
(86) PCT No.: PCT/US2012/044346

§ 371 Date: Mar. 26, 2014

Related U.S. Application Data
(60) Provisional application No. 61/501,484, filed on Jun. 27, 2011.

(51) Int. Cl. H01L 31/0216; H01L 31/18; H01L 31/0224

(52) U.S. Cl. CPC H01L 31/02168; H01L 31/022466; H01L 31/022425; H01L 31/1884; H01L 31/1804
USPC 136/256; 438/98

(57) ABSTRACT

Super-transparent electrodes for photovoltaic applications are disclosed. In some embodiments, a photovoltaic cell (1) includes an absorber material (16) capable of absorbing solar energy and converting the absorbed energy into electrical current; a window electrode (10) disposed on a light-entry surface of the absorber material (16), the window electrode (10) comprising an anti-reflective coating (ARC) layer (12) and a metallic layer (13), and a rear electrode (18) disposed on a surface of the absorber material (16) in opposing relation to the window electrode (10), wherein the rear electrode (18) in combination with the window electrode (10) are configured to collect electrical current generated in the absorber material (16).

### RELATED APPLICATIONS

This application claims the benefit of and priority to U.S. Provisional Application Ser. No. 61/501,484, filed Jun. 27, 2011, which is incorporated herein by reference in its entirety.

### STATEMENT OF GOVERNMENT SUPPORT

This invention was made with government support under grant no. DE-FG02-00ER45805 awarded by the U.S. Department of Energy. The U.S. Government has certain rights to the present invention.

### FIELD

The embodiments disclosed herein relate to light-entry electrodes for photovoltaic cells, and more particularly to electrodes comprising an antireflective layer and a metallic layer.

### BACKGROUND

A typical conventional solar cell contains a light absorber, such as amorphous or crystalline silicon, sandwiched between two electrodes. One of the electrodes is typically transparent. An incident light creates carriers in the absorber, which subsequently are collected through the electrodes. Because the top electrode (ITO in a-Si or a highly doped surface layer in c-Si is usually insufficiently conductive, current collection fingers are typically placed on the light-absorbing surface of the absorber. The presence of collection fingers, however, reduces the active surface area of the absorber.

### SUMMARY

Super-transparent electrodes for photovoltaic applications are disclosed herein. According to an aspect illustrated herein, there is provided a light entry electrode that includes an anti-reflective coating (ARC) layer; and a nanoscopically perforated metallic film.

According to some aspects illustrated herein, there is provided a photovoltaic cell that includes an absorber material capable of absorbing solar energy and converting the absorbed energy into electrical current; a window electrode disposed on a light-entry surface of the absorber material, the window electrode comprising an anti-reflective coating (ARC) layer and a nanoscopically perforated metallic film; and a rear electrode disposed on a surface of the absorber material in opposing relation to the window electrode, wherein the rear electrode in combination with the window electrode are configured to collect electrical current generated in the absorber material.

According to some aspects illustrated herein, there is provided a photovoltaic cell that includes an absorber material capable of absorbing solar energy and converting the absorbed energy into electrical current, the absorber material having a light-entry surface comprising a plurality of hills; a window electrode disposed on the light-entry surface of the absorber material, the window electrode comprising a network of metallic nanowires disposed along the valleys of the absorber material and an antireflective coating layer deposited over the network; and a rear electrode disposed on a surface of the absorber material in opposing relation to the window electrode, wherein the rear electrode in combination with the window electrode are configured to collect electrical current generated in the absorber material.

According to some aspects illustrated herein, there is provided a method for forming a solar cell that includes forming a window electrode on a light-entry surface of an absorber material capable of absorbing solar energy and converting the absorbed energy into electrical current, wherein the window electrode comprises an anti-reflective coating (ARC) layer and a metallic layer; connecting a rear electrode to a surface of the absorber material in opposing relation to the window electrode; and configuring the rear electrode in combination with the window electrode to collect electrical current generated in the absorber material.

### BRIEF DESCRIPTION OF THE DRAWINGS

The presently disclosed embodiments will be further explained with reference to the attached drawings, wherein like structures are referred to by like numerals throughout the several views. The drawings shown are not necessarily to scale, with emphasis instead generally being placed upon illustrating the principles of the presently disclosed embodiments.

FIG. 1 is a schematic diagram of an embodiment of a coating of the present disclosure on an absorber material.

FIG. 2 is a front view of an embodiment of a metallic film of the present disclosure.

FIG. 3 presents embodiment unit cells of the planar structures of the metallic film pierced with a hexagonal array of circular holes. Metal is shown in black. The numbers at the hole center represent the ratio of the hole diameter to the array period.

FIG. 4A and FIG. 4B are schematic diagrams of an embodiment of a coating of the present disclosure on a textured absorber material.

FIG. 5 presents simulated results for the amorphous silicon absorber material (Dashed line: reflectance of the metal-free absorber material. Dashed-bold line: reflectance of the absorber material coated with the metallic film of FIG. 1, with the center-to-center hole distance of a=440 nm, and the hole diameter d=420 nm. Solid line: reflectance of the metal-free absorber material with ARC. Solid-bold line: the same as the solid line, but with the metallic film included).

FIG. 6A and FIG. 6B present simulated results for the crystalline silicon absorber material (Blue line: reflectance of the metal-free absorber material. Green line: reflectance of the absorber material coated with the metallic film. Red line: reflectance of the metal-free absorber material with ARC. Black line: the same as the red line, but with the metallic film included). FIG. 6A presents results for the 420/440 metallic structure and FIG. 6B presents results for the 390/440 metallic structure.

FIG. 7 is a SEM image of the 690/840 structure in 30 nm thick Ag film.

FIG. 8 presents experimental and simulated results for the 690/840 structure in the 30 nm thick Ag film.

FIG. 9A presents simulated reflectance for 30 nm thick silver film having 420/440 hexagonal array.

FIG. 9B presents simulated reflectance for 30 nm thick silver film having 390/440 hexagonal array.

FIG. 10 illustrates measured reflectance for a perforated metallic film having 390/470 array of holes.

FIG. 11 illustrates simulated reflectance for a perforated metallic film having 390/470 array of holes.

FIGS. 12A-12D present a schematic diagram of a fabrication process for samples having metallic nanowire network electrode in combination with ARC.

FIG. 13A presents an SEM image of nanoparticles on a surface of textured silicone before sintering.

FIG. 13B presents an SEM image of nanoparticles on a surface of textured silicone after microwave sintering.

FIG. 13C presents an SEM image of nanoparticles on a surface of textured silicone after furnace sintering.

FIG. 14A and FIG. 14B present electrical and optical measurements of the nanowire network electrodes as a function of the density of the nanoparticles forming the network.

FIG. 15 presents reflectance spectra for textured silicone alone, textured silicone with an anti-reflective coating, textured silicon with nanoparticles networks, and textured silicon with nanoparticles networks and anti-reflective coating.

While the above-identified drawings set forth presently disclosed embodiments, other embodiments are also contemplated, as noted in the discussion. This disclosure presents illustrative embodiments by way of representation and not limitation. Numerous other modifications and embodiments can be devised by those skilled in the art which fall within the scope and spirit of the principles of the presently disclosed embodiments.

### DETAILED DESCRIPTION

The present disclosure provides a new type of conductive coatings that can dramatically increase conductivity of a solar absorber surface, while preserving its high transparency and the efficiency of the anti-reflection coating. In some embodiments, the coatings include a conductive metal layer in combination with an anti-reflective coating (ARC). The coatings of the present disclosure can be applied to the surface through which light enters a solar absorber to act as a light entry (top) electrode.

By plasmonic action, the coatings of the present disclosure may be designed to be simultaneously highly conductive and transparent in a broad range of light spectrum when placed on a absorber material that has a large refractive index (i.e., silicon). In some embodiments, the coatings of the present disclosure may be designed for use with light having a wavelength in the range between 100 nm and 1 mm. In some embodiments, the coating of the present disclosure may be designed for use in Ultraviolet range, Visible range, Infrared range or combinations thereof. In some embodiments, the coating of the present disclosure may be optimized for use with visible light.

In some embodiments, the presence of the ARC unexpectedly increases transparency of the properly designed metallic layer in the presence of a solar absorber with a large dielectric constant. This phenomenon is called super-transmission, and unexpectedly it is actually improved by the presence of the ARC. Normally, such a metallic layer has only a limited transparency. However, with an anti-reflective coating placed on top of the metallic layer, the metallic layer becomes super-transparent and thus does not interfere with action of the ARC such that the reflection is efficiently suppressed in a broad range of frequencies. In some embodiments, combining a properly designed metallic layer with the ARC may enable the ARC to suppress reflection in a broader range than if the metallic film was not present. In addition, the coatings of the present disclosure remain conductive, and thus are suitable for use as a window electrode.

In the context of a solar cell, the advantages of the coatings of the present disclosure include, but are not limited to, reducing or eliminating the need for the metallic fingers currently employed to collect the current. These metallic fingers reduce the effective surface area of the cells, and, by eliminating them, one can increase the efficiency of the solar cell.

Both the metallic film and the ARC can be deposited inexpensively on top of commercially-available solar cells. The gain in efficiency is primarily due to the increased surface area of the cell resulting from the elimination of the current collection fingers. In some embodiments, the gain in efficiency is between about 5% and about 10%. In some embodiments, the gain in efficiency is about 20%. The existing process for deposition of the ARC can remain unchanged, allowing the additional processing step of film deposition to be seamlessly included in the production line. In some embodiments, the deposition of the metallic film can be accomplished by either the nanosphere lithography, nano-imprint lithography or even spray coating with proper nanoparticles that can provide a random metallic network below the percolation threshold.

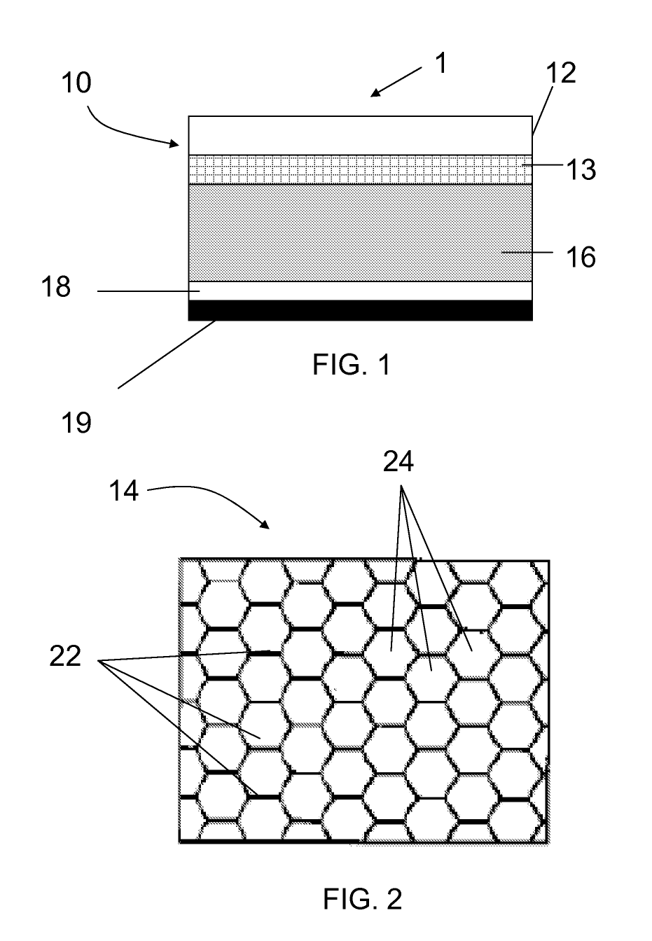

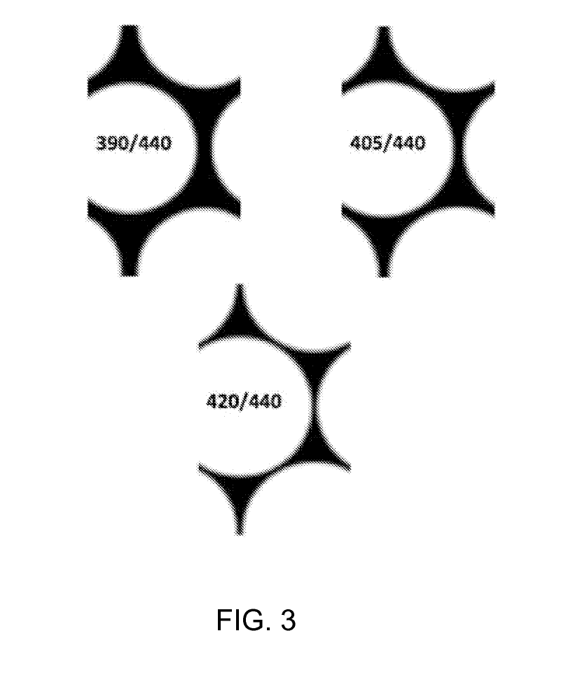

According to aspects illustrated herein, as shown in FIG. 1, there is provided a conductive coating 10 that includes an anti-reflective coating (ARC) layer 12 and a metallic layer 13. As shown in FIG. 2, in some embodiments, the metallic layer 13 comprises a perforated metallic film 14.

In the embodiment where the perforated metallic layer 14 has circular holes, and which have a diameter in the short wavelength limit, i.e., d>>λ, the reflectance increases due to the presence of the film on a solar absorber is simply

ΔR≈v(1−R₀) (1)

where R₀ is the reflectance from the absorber material alone, and the surface fraction of metal in the film v is given here by

$$v = 1 - {( \frac{d}{a} )}^{2} \frac{π}{2 \sqrt{3}} \qquad ( 2 )$$

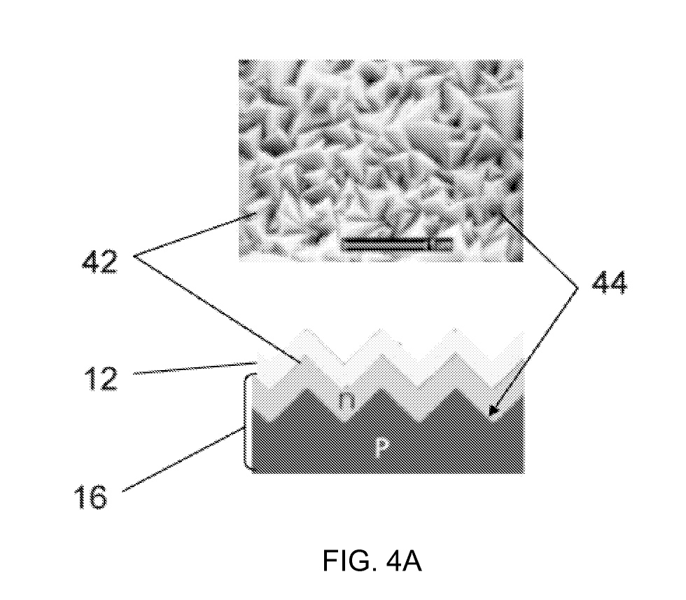

By way of example, if the absorber material is silicon (R₀≈0.5), the hexagonal structures in FIG. 3 from left to right (films with the ratio of the hole diameter to the array period of 390/440, 405/440, 420/440) yield ΔR≈0.15, 0.12, and 0.09, respectively, which may be too large for certain applications.

In some embodiments, the holes 22 have a diameter in the sub-wavelength limit, i.e., d<<λ. In this effective medium case, the metallic film can be treated as a substantially uniform metallic film with an effective dielectric function given by:

$${ɛ}_{f} \approx {\overline{ɛ}}_{b} - \frac{{\overline{ω}}_{p}^{2}}{{ω}^{2}} \qquad ( 3 )$$

where

ε̅_{b}=ε_{b}v+ε_{back}(1−v) (4)

and the reduced plasma frequency is

ω̅ₚωₚ\sqrt{v} (5)

For this film of thickness t_{f}<<λ, the reflectance change is:

ΔR=A(ε_{f}−ε₀)(ε_{f}−ε_{sub}) (6)

where

$$A = \frac{4 {π}^{2} {n}_{0} {n}_{sub}}{{( {n}_{0} + {n}_{sub} )}^{4}} {( \frac{{t}_{f}}{λ} )}^{2} > 0 \qquad ( 7 )$$

Equation (6) shows, that now ΔR depends strongly on the dielectric environment around the film. For ε_{sub}=ε₀

ΔR=A(ε_{f}−ε₀)²>0 (8)

which means that in this case, the presence of the metallic film increases the reflectance, similarly to the case of the short wavelength limit discussed above. However, the reflectance increase is now much smaller, because

$$Δ R \sim A \sim {( \frac{{t}_{f}}{λ} )}^{2} << 1.$$

Moreover, for ε_{sub}>ε₀, the frequency window exists, in which

ε_{0<}ε_{f}<ε_{sub} (9)

and where ΔR<0, according to Equation (6). In that case, the presence of the metallic film actually reduces the reflectance, i.e., the film becomes super-transparent. In some embodiments, the super-transparency occurs for λ<500 nm, i.e., in the visible range. Note, that condition ε₀<ε_{f}<ε_{sub} simply assures a more gradual transition of the refractive index into the absorber material, a well-known method of improving the wave impedance matching.

In some embodiments, ARC is a dielectric film of thickness t, and refractive index n₀, placed on a absorber material with refractive index n₂. It eliminates reflection of light at a frequency ω (vacuum wavelength λ), provided that

n₀=\sqrt{n₂} (10)

and

t=λ/4n₀ (11)

Even though a photonic resonance (phase cancellation) is needed for a perfect ARC action, an imperfect reflectance suppression occurs in a relatively broad range of frequencies. Combining the ARC layer 12 with the metallic film 14 leads to a substantially unobstructed anti-reflection action in a broad range of frequencies. The reflectance of the combination of the ARC layer 12 and metallic film layer 14, with the ARC conditions (Equation 10 and Equation 11) satisfied, is

$$R = {( {r}_{AR C} )}^{2} \approx \frac{Δ {R}^{2}}{4 {{r}_{v}^{2} ( 1 - {r}_{v}^{2} )}^{2}} = {B ( \frac{{t}_{f}}{λ} )}^{4} \qquad ( 12 )$$

where

$$B = \frac{1}{4} {( \frac{π}{{n}_{0}} )}^{4} {( \frac{1 + {n}_{0}}{1 - {n}_{0}} )}^{2} \qquad ( 13 )$$

In Equation (12) R is proportional to the 4^{th} power of t_{f}/λ<<1, and thus the suppression of the reflection is nearly exact, as in the original ARC. The ARC action is essentially unaffected by the presence of the film; the film appears “invisible”, or it is efficiently cloaked by ARC. Thus the ARC action occurs at the usual conditions (Equation 10 and Equation 11), and the suppression of the reflectance is essentially identical to that without the metallic film. Moreover, the metallic film may also appear invisible if its dimensions are only slightly subwavelength or similar to the wavelength.

The ARC layer 12 may be deposited over a surface of an absorber material and is designed to increase transmittance of light into the absorber material by reducing the amount of light that is reflected by the absorber material and the metallic film 14. The ARC coating layer may comprise a single coating layer or multiple coating layers. In some embodiments, the ARC layer 12 is a film of dielectric material. In some embodiments, the ARC layer 12 is an oxide, fluoride, nitride, or sulfide of a metal or metalloid, including, but not limited to, silicon (Si), magnesium (Mg), Zink (Zn), Titanium (Ti), Tin (Sn), Cerium (Ce) and similar materials. Suitable specific examples of suitable anti-reflective coatings include, but not limited to, MgF₂, ZnS, MgF₂, TiO₂, SiO₂, SiNₓ, CeO₂ and similar materials. Other known and commonly used antireflective coatings may also be used with embodiments disclosed herein.

In some embodiments, the thickness of the ARC layer 12 is governed by Equation (11), above, and is subwavelength. In some embodiments, the thickness of the ARC layer 12 is less than 100 nm. In some embodiments, the thickness of the ARC layer 12 is less than 50 nm. In some embodiments, the thickness of the ARC layer 12 is less than 500 nm. In some embodiments, the thickness of the metallic film layer 14 is subwavelength. In some embodiments, the thickness of the metallic film layer 14 is less than 100 nm. In some embodiments, the thickness of the metallic film layer 14 is less than 50 nm. In some embodiments, the thickness of the metallic film layer 14 is less than 500 nm.

In reference to FIG. 2, in some embodiments, the metallic film 14 includes an array of holes 22 separated by lines of metal 24.

In some embodiments, the array of holes 22 has an array period (a) ranging between about 100 nm and about 1000 nm. In some embodiments, the array period is subwavelength. In some embodiments, the array period is less than 5000 nm. In some embodiments, the array period is less than 400 nm. The array may be either periodic or non-periodic. The array can be of any shape, including, but not limited to, hexagonal, honeycomb, square, rectangular, triangular or completely random. In some embodiments, the coatings of the present disclosure may be optimized for a desired light range by modifying the array period, hole sizes, or both of the metallic film 14.

In some embodiments, the holes 22 can have a diameter (d) between about 70 nm and about 1000 nm. In some embodiments, the holes 22 have a diameter in the sub-wavelength limit, i.e. hole diameter is smaller than the received wavelength. In some embodiments, the holes 22 have a diameter less than 500 nm. In some embodiments, the holes 22 have a diameter less than 400 nm. The holes can also be of any shape, including, without limitation, circular, elliptical, square, triangular, and the like. In some embodiments, the shape of the holes 22, dimension of the holes 22, and distribution of the holes 22 are selected so that the structure of the metallic film 14 is at or near percolation threshold. In some embodiments, the metallic film 14 is a hexagonal array of nearly touching circular holes 22 (Escheric series). In another embodiment, the metallic film 14 is an array of nearly touching square holes (checkerboard series).

By way of a non-limiting example, FIG. 3 illustrates unit cells of the planar structures of an embodiment of the metallic film 14 with pierced with a hexagonal array of circular holes 22. Metal 24 is shown in black. The numbers at the hole center represent the ratio of the hole diameter to the array period.

In some embodiments, the metallic film 14 is made of a conductive metal to allow the coatings of the present disclosure to be used as an electrode. Suitable metals include, but are not limited to, silver (Ag), copper (Cu), gold (Au), properly corrosion protected alkali metals, such as aluminum (Al), sodium (Na), potassium (K), etc., among many similar metals

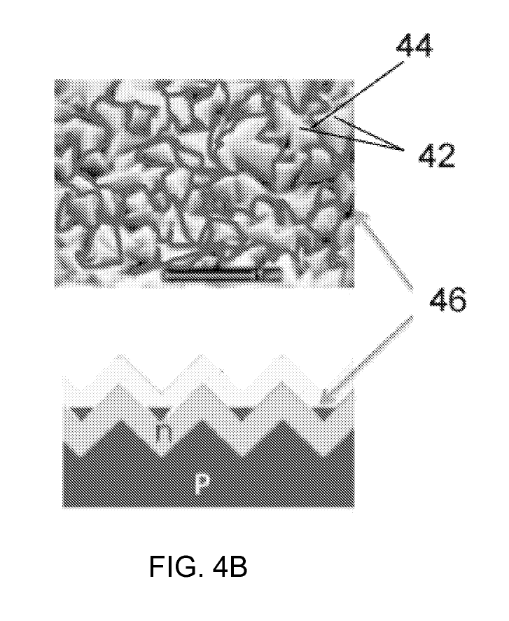

In reference to FIG. 4A and FIG. 4B, in some embodiments, the metallic layer 13 is a network of metallic nano wires or strands 46. In some embodiments, the metallic network 46 may be assembled from a plurality of conductive metal nanoparticles connected together to form nano wires or strands and to provide electrical conductivity through the metallic network 46. In some embodiments, the nanoparticles have a diameter between 5 and 200 nm. In some embodiments, the thickness of the metallic network is subwavelength. In some embodiments, the thickness of the metallic network is less than 500 nm.

In some embodiments, the metallic network 46 may be deposited over a randomly textured surface of an absorber material. A surface of an absorber material may be textured to form a pattern of random hills 42 and valleys 44, and the metallic network may be extended along the valleys 44. In some embodiments, the hills 42 are in the shape of pyramids having a height and width between about 0.5 to about 10 microns. The separation distance between the pyramids may range from about 1.5 to about 15 microns.

According to aspects illustrated herein, as shown in FIG. 1, there is provided a photovoltaic cell 1 that includes a conductive coating 10 of the present disclosure disposed on the light absorbing surface of an absorber material 16. The conductive coating 10 thus acts as a front electrode of the photovoltaic cell 1.

In some embodiments, the absorber material 16 is capable of absorbing solar energy and converting the absorbed energy into electrical current. In some embodiments, the absorber material is a semiconductor or photovoltaic junction. In some embodiments, the absorber material is a p-n junction. In some embodiments, the absorber material is a p-i-n junction. In some embodiments, the coating 10 is deposited over the p-doped side of a p-n junction or a p-i-n junction. In some embodiments, the coating 10 is deposited over the n-doped side of a p-n junction or a p-i-n junction. In some embodiments, the absorber material is selected from semiconductor materials, including, without limitations, group IV semiconductor materials, such as amorphous silicon, hydrogenated amorphous silicon, crystalline silicon (e.g., microcrystalline silicon or polycrystalline silicon), and germanium, group III-V semiconductor materials, such as gallium arsenide and indium phosphide, group II-VI semiconductor materials, such as cadmium selenide and cadmium telluride, chalcogen semiconductor materials, such as copper indium selenide (CIS) and copper indium gallium selenide (CIGS). In some embodiments, the absorber material 16 is made of a material having a refractive index of greater than 3. In some embodiments, the absorber material 16 is made of a material having a refractive index of greater than 4. In some embodiments, the coatings of the present disclosure can be used in combination with high efficiency crystalline solar cells.

In some embodiments, the coating 10 is deposited on a flat surface of an absorber material 16, as illustrated in FIG. 1. In some embodiments, the coating 10 is deposited on a textured surface of the absorber material 16, as shown in FIG. 4A and FIG. 4B. In some embodiments, the absorber material 16 can be textured by chemical etching. In some embodiments, the textured surface may be a random network of pyramids 42 separated by valleys 44, as shown in FIG. 4A. In some embodiments, the network is topologically equivalent to the network of holes in the metallic film, such that the networks 46 of metallic material of the metallic film 14 are deposited in the valleys 44 between the pyramids 42 of the absorber material texture, as shown in FIG. 4B.

The coating 10 may be deposited on the absorber material 16 by any fabrication method known in the art. In some embodiments, the coating 10 can be applied to the surface of the absorber material by using nanosphere lithography, a technique that produces thin metallic films perforated with periodic arrays of holes, in particular sub-wavelength holes.

In some embodiments, the metallic layer 13 may be fabricated by self-assembly. In some embodiments of this method, one can immerse the textured absorber material (without ARC) in a solution of metallic magnetic nanoparticles (e.g., Ni). By applying a constant magnetic field, these particles can be attracted to the structure, and self-assemble in the valleys in-between the pyramids. The thermal processing will then develop a continuous metallic network, like that shown in FIG. 4B. Subsequently, one could electro-deposit metal, and finally the ARC film. In some embodiments, the metallic film may be self-assembled by metal deposition on the textured absorber material and thermal processing. In this method, after a proper thermal processing and surface preparation, a metallic film coated on textured surface melts, and flows into the valleys, yielding naturally the metallic network as in FIG. 4B. Another possible fabrication involves the silver mirror reaction, combined with properly treated textured surface of the absorber material. Another possible fabrication method is texturing by etch. In this method, one could develop a perforated film on a planar, p-doped absorber material. Then, this film could be used as a mask for the subsequent absorber material etch, resulting in deep cavities at the hole locations. This will act as an inverted texture. Subsequent steps could be the n-doping and the ARC film deposition. It should of course be understood that the methods of fabrication described herein are provided by the way of example and not limitation, and thus other known methods may be used to deposit the coating 10 on the absorber material 16.

Referring back to FIG. 1, the photovoltaic cell 1 further includes a rear electrode 18 disposed on the back side of the absorber material 16, that is, the side opposite the light absorbing surface of the absorber material 16. The rear electrode 18 may be made of a metal, such as, by example, aluminum, gold or another conductive metal. The rear electrode 18, in combination with the conductive coating of the present disclosure, collect electrical current generated in the absorber material 16. The photovoltaic cell 1 may also include a substrate 19, which may provide additional structural support for the photovoltaic cell 1. In some embodiments, the substrate 19 may be made of glass or metal.

### EXAMPLES

Examples (actual and simulated) of using the coatings of the present disclosure on a absorber material are provided below. These examples are merely representative and should not be used to limit the scope of the present disclosure. A large variety of alternative designs exist for the methods and devices disclosed herein and are within the spirit and the scope of the present disclosure. The selected examples are therefore used mostly to demonstrate the principles of the methods and devices disclosed herein.

### Example 1

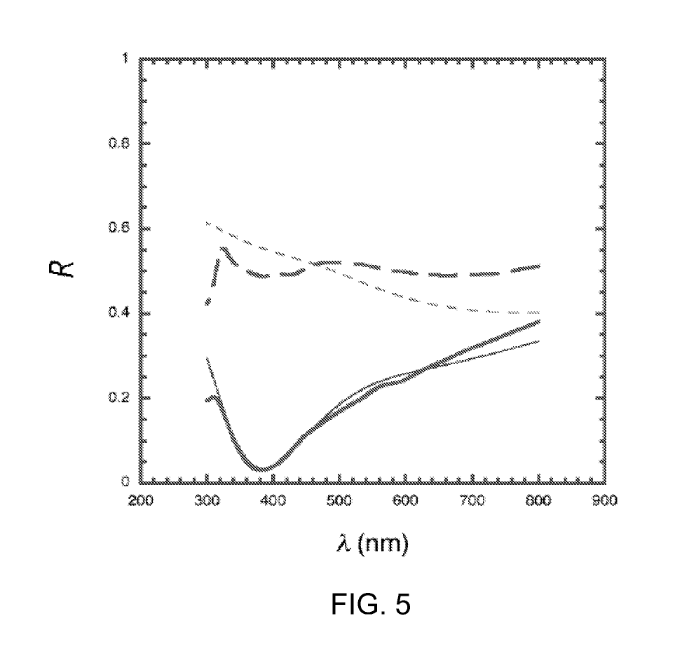

FIG. 5 shows the simulated reflectance of the metal-free absorber material (dashed line), reflectance of the absorber material coated with the metallic film of FIG. 3, with the center-to-center hole distance of a=440 nm, and the hole diameter d=420 nm (dashed bold line), reflectance of the metal-free absorber material with ARC (t=40 nm, n₀ taken from U. C. Fischer, H. P. Zingsheim, J. Vac. Sci. Technol., 19, 881 (1981)) (solid line), and reflectance of the absorber material with ARC (t=40 nm, n₀ taken from U. C. Fischer, H. P. Zingsheim, J. Vac. Sci. Technol., 19, 881 (1981)) (solid-bold line). The absorber material is assumed to be amorphous silicon (a-Si).

In the visible range |ΔR|<0.1, and for wavelength <460 nm ΔR<0, i.e., the metallic film is super-transparent, in qualitative agreement with the effective medium predictions above. FIG. 5 shows also the reflectance of this structure with ARC, with (solid-bold line), and without (solid line) the metallic film.

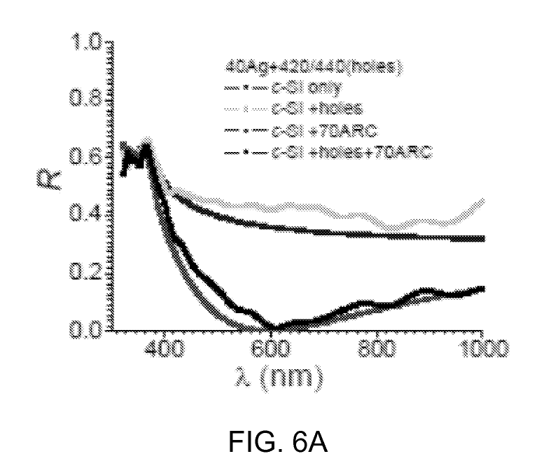

FIG. 6A and FIG. 6B show the analogous result for the crystalline silicon absorber material. Here the ARC layer was chosen to have thickness t=70 nm, to provide the reflectance minimum at about 560 nm. Results for two metallic structures are shown: structure 420/440 in FIG. 6A, and structure 390/440 in FIG. 6B. In each case, the metallic film approaches super-transparency for λ<400 nm, and in the presence of ARC is practically “invisible” in the entire visible range.

Next, a series of experiments was performed. First, samples of c-Si coated with the structure 690/840 in the 30 nm Ag film, antireflective coating or both made were fabricated.

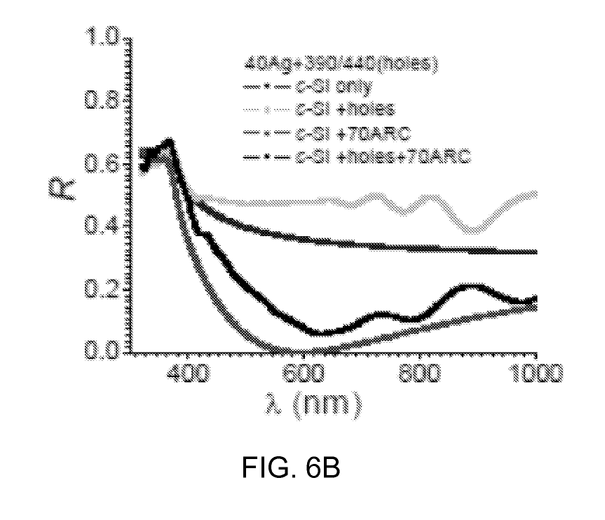

FIG. 7 shows SEM of 30 nm Ag film with the 690/840 perforation pattern used for these experiments. Measurements of the reflectance were made by employing the FTIR spectrometer.

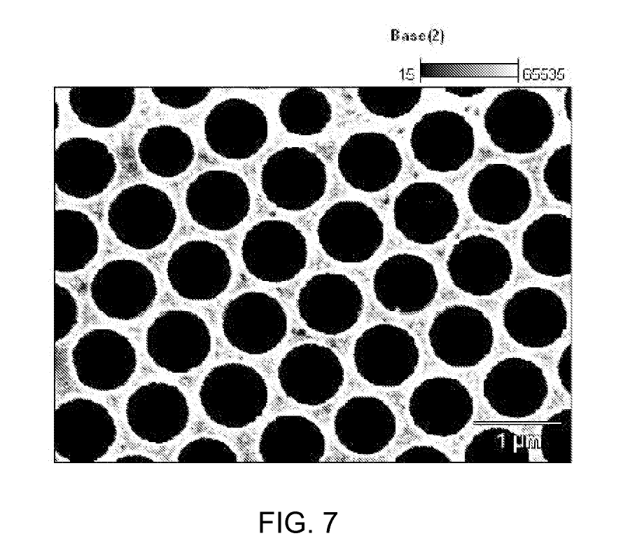

FIG. 8 shows the experimental and simulated results for c-Si alone, c-Si with the metallic film, and c-Si with the metallic film coated with the anti-reflective coating.

### Example 2

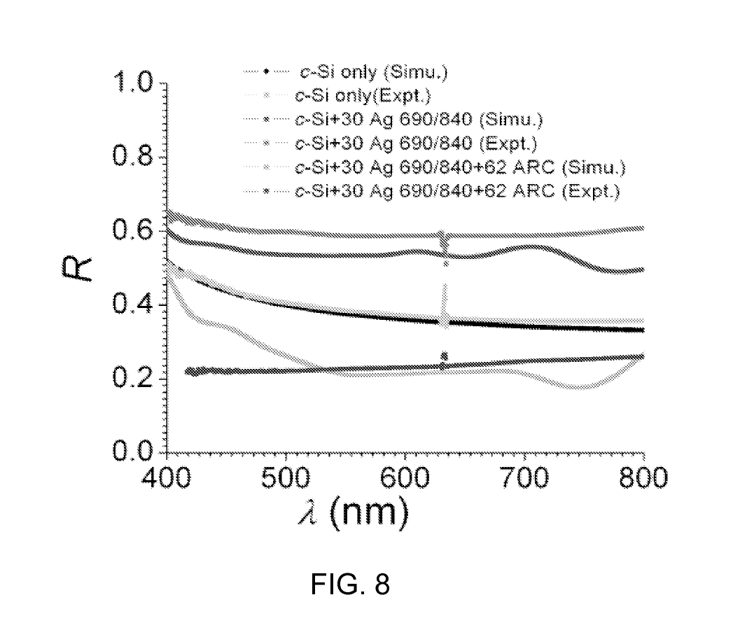

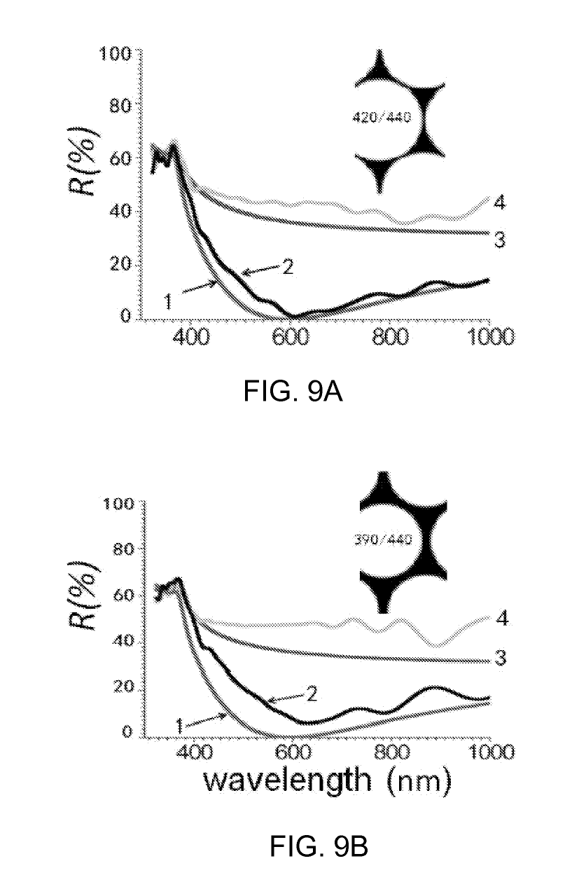

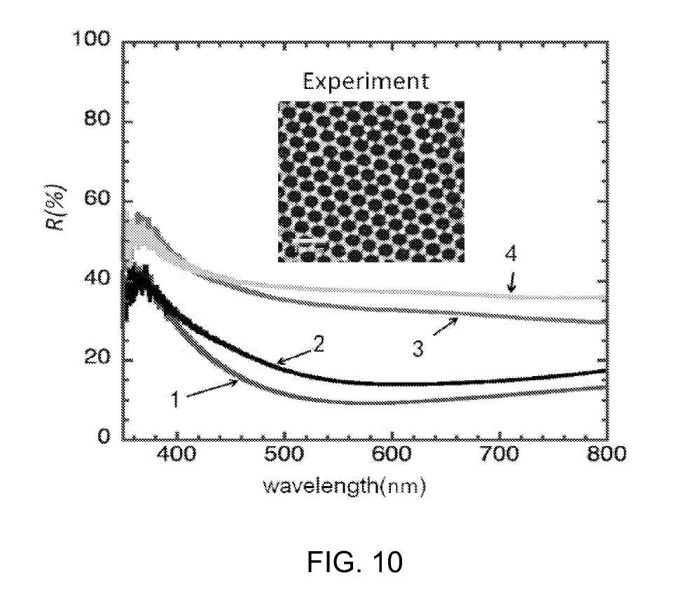

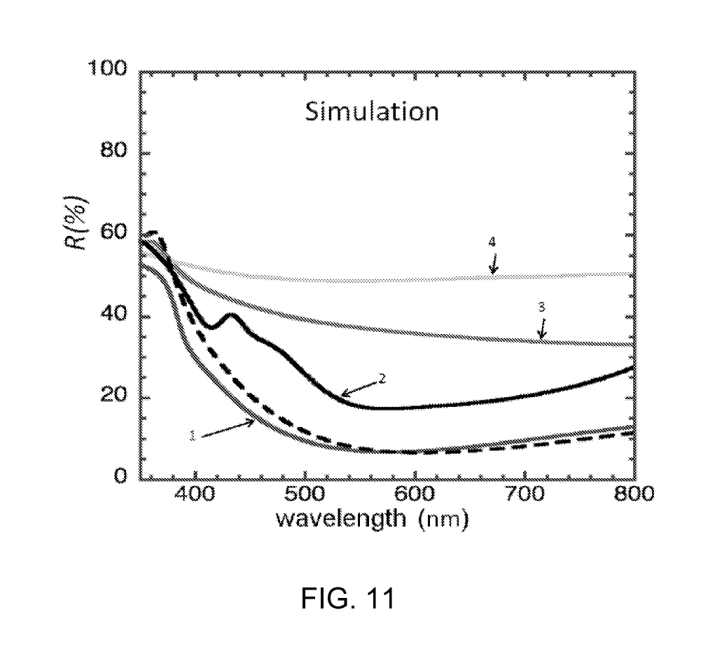

FIG. 9A and FIG. 9B show simulated reflectance (using the MEEP code [see MIT Electromagnetic Equation Propagation, http://ab-initio.mit.edu/wiki/index.php/Meep]) for samples of crystalline silicon coated with nanoscopically perforated metallic film (NPMF) and ARC (70 nm of ITO). FIG. 9A presents results for 30 nm thick silver film having 420/440 hexagonal array. FIG. 9B presents results for 30 nm thick silver film having 390/440 hexagonal array. In each of FIG. 9A and FIG. 9B, the reflectance lines are numbered as the corresponding structures: 1—silicon substrate coated with ARC, 2—complete structure of silicon substrate coated with NPMF and ARC; 3—silicon substrate alone, and 4—silicon substrate coated with NPMF. This numbering convention is also used in FIG. 10 and FIG. 11.

As can be seen from FIG. 9A and FIG. 9B, firstly, the reflectance represented by line 4 is close, but greater than that for line 3, i.e. ΔR>0. Secondly, for λ<400 nm, lines 4 and 3 seem to cross, as predicted. Thirdly, lines 1 and 2 are very close in the case of the “420/440” NPMF (a=440 nm, d=420 nm), as shown in FIG. 9A. This shows that this NPMF is effectively cloaked. For the NPMF with smaller holes shown in FIG. 9B, the cloaking is less efficient, but still apparent.

FIG. 10 illustrates measured reflectance of a silicon wafer (line 3), a wafer with ARC (88 nm SiOx, line 1), a wafer with 390/470 NPMF (line 4) and a wafer with both NPMF and ARC (line 2). The inset shows the AFM image of the NPMF used in this experiment.

Polished crystalline silicon wafers were used in this series of experiments. The reflection spectra were collected using Ocean Optics ISP-REF integrating sphere. Line 1 in this figure was taken for a sample obtained by coating the wafer with an 88 nm thick, sputtered SiO2 film as ARC (ORION-8 Sputtering system, AJA International Inc.). The NPMF was obtained by employing the nanosphere lithography (NSL) (see U. C. Fischer and H. P. Zingsheim, “Submicroscopic pattern replication with visible light”, J. Vac. Sci. Technol., 19, 881 (1981)). A shadow mask for the evaporation of silver was prepared as follows. First, a monocrystalline monolayer of polystyrene beads with a diameter of 470 nm was self-assembled at a water-air interface, and subsequently deposited onto a silicon wafer (orientation <100>; purity 99.99%; surface roughness <1 nm). Thermal processing was used to affix the beads to the silicon surface, and subsequently the reactive ion etching (RIE) was used to reduce the sphere diameters to 390 nm. The array of beads was used as a shadow mask for evaporation of silver. After evaporation the beads of the shadow mask were chemically removed, leaving behind on the silicon wafer surface a metallic negative of the shadow mask: a silver film of 30 nm thickness, perforated with a hexagonal pattern of holes (with a=470 nm, and d=390 nm); this is the NPMF. Typical atomic force microscope (AFM) of this NPMF is shown in the inset of FIG. 10, obtained with the Dimension 3100 AFM microscope (with Nanoscope IV controller from Veeco). Line 4 in FIG. 10 shows the reflectance of a wafer coated with the NPMF, and line 2 shows the reflectance of the complete structure with NPMF and ARC. The measured reflectance of the complete structure (line 2 in FIG. 10) is well below 20% in the visible range, in spite of the NPMF present, and only about 5% larger than the reflectance of the structure with ARC alone (line 1 in FIG. 10).

In reference to FIG. 11, solid lines represent simulated reflectance of the corresponding cases in FIG. 10, obtained by using finite difference frequency domain (FDFD) method (CFT code [Computer Simulation Technology Microwave Studio, http://www.cst.com]). Dashed line in FIG. 11 represents simulated reflectance of 390/470 NPMF and ARC on silicon wafer using the finite difference time domain (FDTD) method (MEEP code). The simulations are generally in qualitative agreement with the longwavelength analysis above, and supports the qualitative behavior of the 1-4 lines (in all panels of FIGS. 9, 10 and 11).

### Example 3

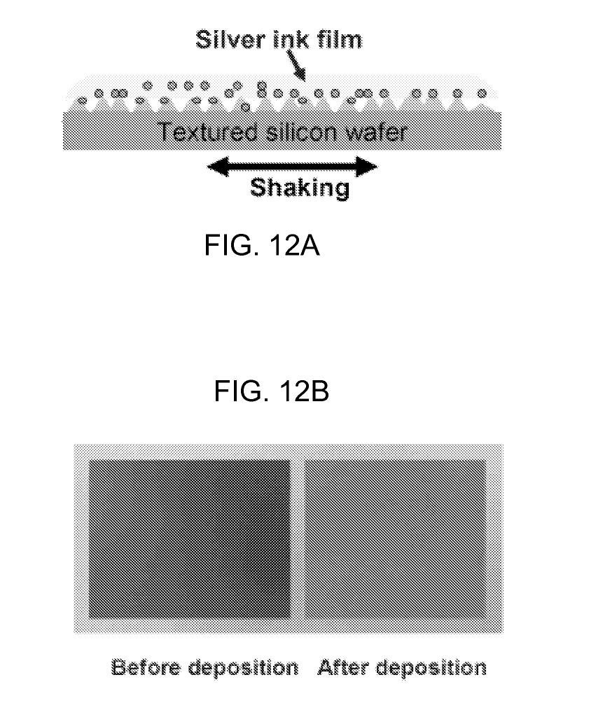

FIGS. 12A-12D present a schematic diagram of a fabrication process for samples having metallic nanowire network electrode in combination with ARC. First, silver ink thin film was deposited on textured silicon (tSi) surface, as shown in FIG. 12A. FIG. 12B presents an image of tSi surface before and after the deposition of the nanoparticles on tSi surface. Next, silver nanoparticles (NP) were assembled in the valley on the tSi surface between the pyramids, as shown in FIG. 12C. Finally, the samples were sintered to enable formation of nanowire network electrode (NNE) from the nanoparticles, as shown in FIG. 12D.

The silver ink was produced by a typical wet-chemical method (see, for example, Sun, Y., et al. Polyol synthesis of uniform silver nanowires: a plausible growth mechanism and the supporting evidence. Nano Lett. 2003, 3, 955-960.; Sun, Y.; Xia, Y. Shape-controlled synthesis of gold and silver nanoparticles. Science 2002, 298, 2176.) with NP diameter of 100-200 nm. In particular, silver nitride (0.1M) (99%, Sigma-Aldrich) was reduced in an ethylene glycol solution in the present of PVP (0.6M) (MW≈40000, Sigma-Aldrich) at 170° C., stirring at 2000 rpm for 30 min, where ethylene glycol is both a reducer and a solvent, and PVP is a surfactant. Next, the silver nanoparticles were centrifuged, rinsed and re-dispersed in methanol or ethanol.

The method of thin film-coating involved in this process is a convenient and inexpensive one, similar to that extensively used in the thin film industry (Ahmad, A., et al. Extracellular biosynthesis of silver nanoparticles using the fungus Fusarium oxysporum. Colloid. Surface. B 2003, 28, 313-318.). A thin film of the silver ink was deposited onto the textured surface of a (100) silicon wafer. Within a few minutes the nanoparticles agglomerate/settle into the “valleys” between the pyramids (typically ˜1.5 microns in height and ˜3 microns wide at base). This process was enhanced with mechanical shaking of the wafer.

The samples were then sintered. The microwave sintering was done in a commercial microwave oven operating at 2.46 GHz, with the output power of 80 W. Typical exposure time used was ˜10 second, to selectively heat and sinter the silver nanoparticles into continuous conducting nanowire networks. (See e.g. Perelaer, J.; de Gans, B. J.; Schubert, U.S. Ink-jet Printing and Microwave Sintering of Conductive Silver Tracks. Adv. Mater. 2006, 18, 2101-2104. 10. Roy, R.; Agrawal, D.; Cheng, J.; Gedevanishvili, S. Full sintering of powdered-metal bodies in a microwave field. Nature 1999, 399, 668-669). The furnace sintering was done in a vaccum furnace.

The ARC layer was deposited on the nanowire network using a commercial industrial plasma-enhanced chemical vapor deposition system (PECVD) of OTP Solar (Holland), at the processing temperature of 350° C. The refractive index of SiN is 2.06 and the thickness of the SiN film was about 90 nm, which by design should interference-suppress reflection (by interference) in the middle of the optical range.

The morphologies of samples were characterized by a commercial SEM system (JEOL JCM-5700, Tokyo, Japan). Rₛ of samples was measured by depositing two parallel, narrow (about 2 mm wide) Au strips of length 1.5 cm, and a distance of 1 cm apart. The measured resistance was then properly related to Rₛ. The reflectance was measured by employing the fiber-optic spectrometer (Ocean Optics, USB 4000), and the integration sphere (Ocean Optics, FOIS-1).

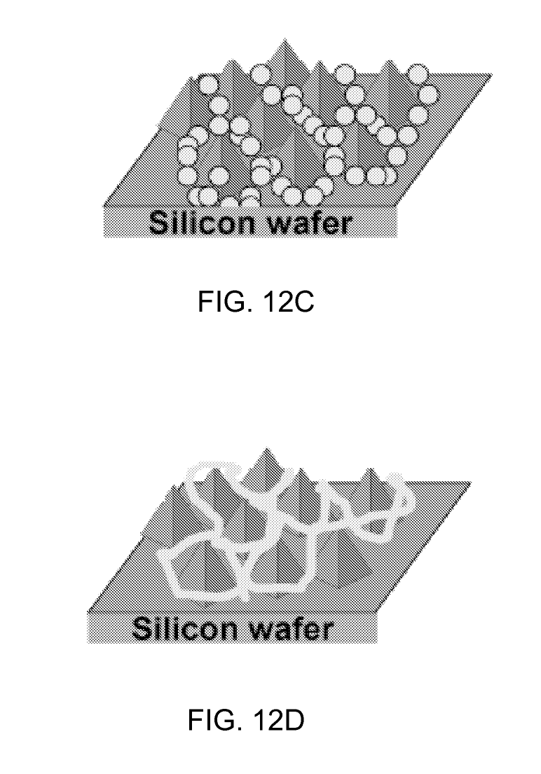

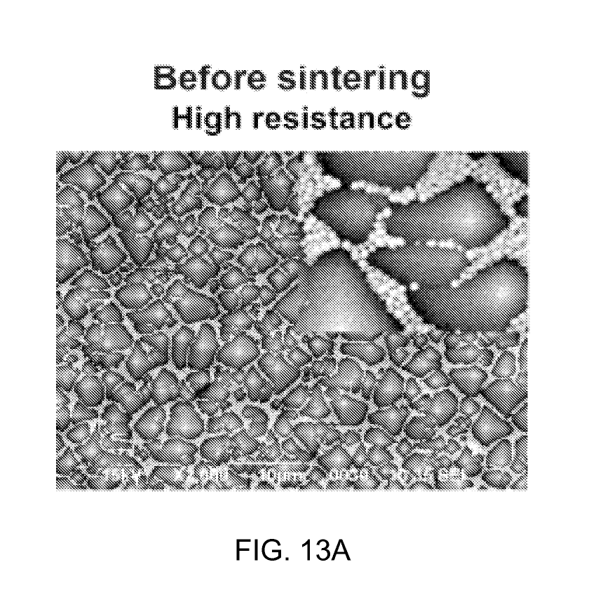

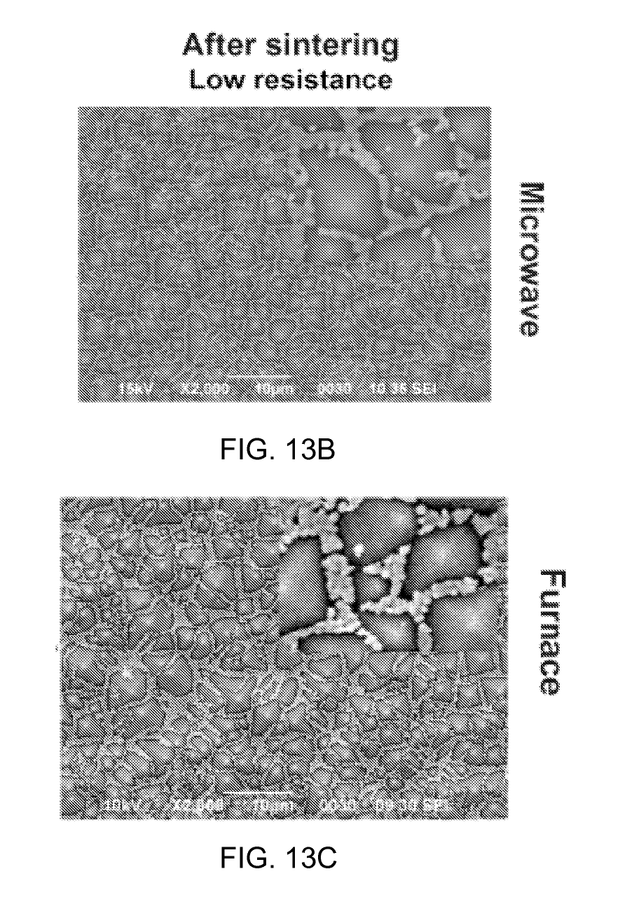

FIG. 13A is an SEM image of nanoparticles on tSi surface before sintering. Continuous paths of touching NPs in the valleys were formed, due to NP density exceeding the percolation threshold. FIG. 13B is an SEM image of nanoparticles on tSi surface after Microwave sintering. FIG. 13C is an SEM image of nanoparticles on tSi surface after furnace sintering. Sintering may remove thin insulating PVP covering the nanoparticles, which are by product of the nanoparticles synthesis. Sintering may also physically connect (pre-melt) the touching NPs and thus to improve the electrical conductivity. The insets, which show zoomed-in sections of the structures, demonstrate stronger pre-melting of NPs in the case of the microwave sintering.

Finally, to complete the structure, silicon nitride ARC film was deposited on top of the NNE.

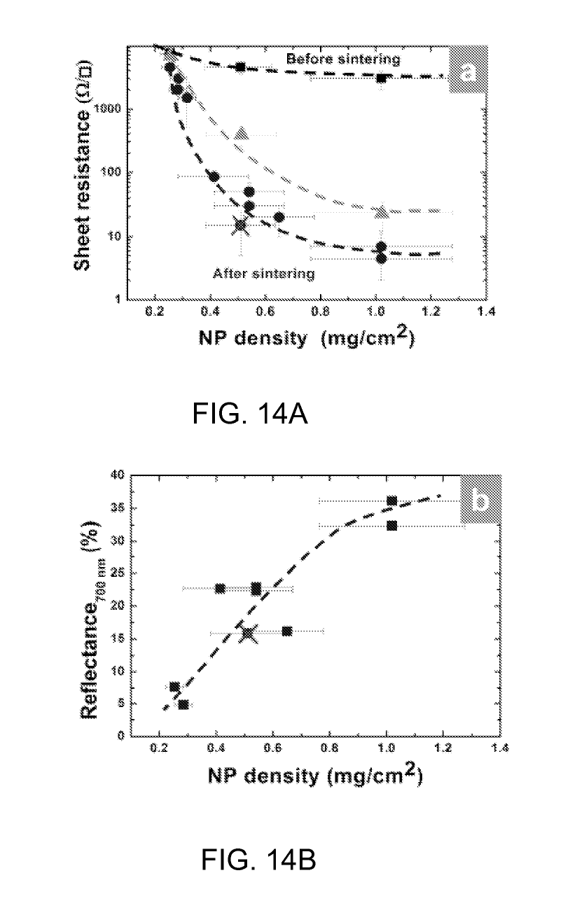

FIG. 14A and FIG. 14B present electrical and optical measurements of the NNE as a function of the density of nanoparticles forming the NNE. Lines in (a) and (b) are a guide to the eye, and crosses indicate an embodiment of a structure of the present disclosure. FIG. 14A presents the measured electrical sheet resistance Rₛ as a function of the NP density for the networks before sintering (squares), and after microwave sintering (circles) and after furnace sintering (triangles). FIG. 14B presents the reflectance R_{700 nm} (measured at the radiation wavelength of λ=700 nm) of the microwave sintered NNE as a function of the NP density. FIG. 14A and FIG. 14B demonstrate that there is a NP density at which the compromise can be achieved between the low resistance and large reflectance of the network. By way of a non-limiting example, the nanoparticles may have the density of about 0.5 mg/cm2, resulting in NNE with Rₛ≈15 Ω/sq and reflectance of R_{700 nm}≈16%.

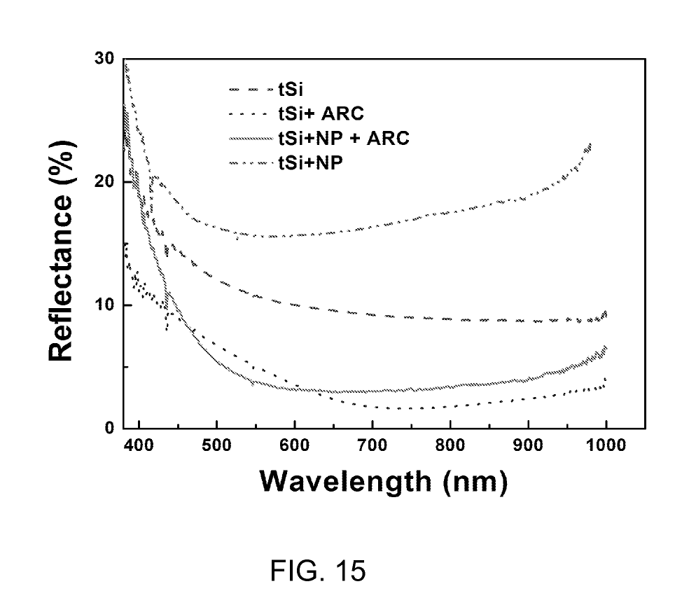

FIG. 15 presents reflectance spectra for tSi alone, tSi with ARC, tSi with NNE, and tSi with NNE and ARC. Structures with ARC with NNE have similar reflectance to structures with ARC without NNE, which is lower than the reflectance of tSi alone and tSi with NNE.

In some embodiments, a light entry transparent electrode that includes an anti-reflective coating (ARC) layer; and a nanoscopically perforated metallic film.

In some embodiments, a photovoltaic cell includes an absorber material capable of absorbing solar energy and converting the absorbed energy into electrical current; a window electrode disposed on a light-entry surface of the absorber material, the window electrode comprising an anti-reflective coating (ARC) layer and a nanoscopically perforated metallic film; and a rear electrode disposed on a surface of the absorber material in opposing relation to the window electrode, wherein the rear electrode in combination with the window electrode are configured to collect electrical current generated in the absorber material.

In some embodiments, a photovoltaic cell includes an absorber material capable of absorbing solar energy and converting the absorbed energy into electrical current, the absorber material having a light-entry surface comprising a plurality of hills; a window electrode disposed on the light-entry surface of the absorber material, the window electrode comprising a network of metallic nanowires disposed along the valleys of the absorber material and an antireflective coating layer deposited over the network; and a rear electrode disposed on a surface of the absorber material in opposing relation to the window electrode, wherein the rear electrode in combination with the window electrode are configured to collect electrical current generated in the absorber material.

In some embodiments, a method for forming a solar cell that includes forming a window electrode on a light-entry surface of an absorber material capable of absorbing solar energy and converting the absorbed energy into electrical current, wherein the window electrode comprises an anti-reflective coating (ARC) layer and a metallic layer; connecting a rear electrode to a surface of the absorber material in opposing relation to the window electrode; and configuring the rear electrode in combination with the window electrode to collect electrical current generated in the absorber material.

All patents, patent applications, and published references cited herein are hereby incorporated by reference in their entirety. While the devices and methods of the present disclosure have been described in connection with the specific embodiments thereof, it will be understood that they are capable of further modification. Furthermore, this application is intended to cover any variations, uses, or adaptations of the devices and methods of the present disclosure, including such departures from the present disclosure as come within known or customary practice in the art to which the devices and methods of the present disclosure pertain, and as fall within the scope of the appended claims.

What is claimed is:

1. A transparent electrode comprising:
an anti-reflective coating (ARC) layer; and
a nanoscopically perforated metallic film.

2. The transparent electrode of claim 1 wherein the metallic film is perforated with an array of holes having a diameter between about 70 nm and about 800 nm.

3. The transparent electrode of claim 1 wherein the metallic film is perforated with an array of holes having a diameter less than about 500 nm.

4. The transparent electrode of claim 1 wherein the metallic film is perforated with an array of holes having an array period between about 100 nm and about 1000 nm.

5. The transparent electrode of claim 1 wherein the metallic film is perforated with an array of holes having an array period less than about 500 nm.

6. The transparent electrode of claim 1 wherein the metallic film is perforated with an array of holes such that the structure of the metallic film is at or near percolation threshold.

7. The transparent electrode of claim 1 wherein the metallic film is perforated with an array of holes such that the structure of the metallic film is substantially at percolation threshold.

8. The transparent electrode of claim 1 wherein the metallic film is a hexagonal array of nearly touching circular holes.

9. The transparent electrode of claim 1 wherein the metallic film is a hexagonal array of nearly touching square holes.

10. A photovoltaic cell comprising:
an absorber material capable of absorbing solar energy and converting the absorbed energy into electrical current;
a window electrode disposed on a light-entry surface of the absorber material, the window electrode comprising an anti-reflective coating (ARC) layer and a nanoscopically perforated metallic film; and
a rear electrode disposed on a surface of the absorber material in opposing relation to the window electrode,
wherein the rear electrode in combination with the window electrode are configured to collect electrical current generated in the absorber material.

11. The photovoltaic cell of claim 10 wherein the absorber material is a p-i-n photovoltaic junction.

12. The photovoltaic cell of claim 10 wherein the absorber material is a p-n photovoltaic junction.

13. The photovoltaic cell of claim 10 wherein the metallic film is perforated with an array of holes having a diameter between about 70 nm and about 800 nm.

14. The photovoltaic cell of claim 10 wherein the metallic film is perforated with an array of holes having a diameter less than about 500 nm.

15. The photovoltaic cell of claim 10 wherein the metallic film is perforated with an array of holes having an array period less than about 500 nm.

16. The photovoltaic cell of claim 10 wherein the metallic film is perforated with an array of holes such that the structure of the metallic film is at or near percolation threshold.

17. The photovoltaic cell of claim 10 wherein the metallic film is perforated with an array of holes such that the structure of the metallic film is substantially at percolation threshold.

18. The photovoltaic cell of claim 10 wherein the metallic film is a hexagonal array of nearly touching circular holes.

19. The photovoltaic cell of claim 10 wherein the metallic film is a hexagonal array of nearly touching square holes.

20. A photovoltaic cell comprising:
an absorber material capable of absorbing solar energy and converting the absorbed energy into electrical current, the absorber material having a light-entry surface comprising a plurality of hills;
a window electrode disposed on the light-entry surface of the absorber material, the window electrode comprising a network of metallic nanowires disposed along the valleys of the absorber material and an antireflective coating layer deposited over the network; and
a rear electrode disposed on a surface of the absorber material in opposing relation to the window electrode,
wherein the rear electrode in combination with the window electrode are configured to collect electrical current generated in the absorber material.

21. A method for forming a solar cell comprising:
forming a window electrode on a light-entry surface of an absorber material capable of absorbing solar energy and converting the absorbed energy into electrical current, wherein the window electrode comprises an anti-reflective coating (ARC) layer and a metallic layer;
connecting a rear electrode to a surface of the absorber material in opposing relation to the window electrode; and
configuring the rear electrode in combination with the window electrode to collect electrical current generated in the absorber material.
